(19) United States
(12) Patent Application Publication
(10) Pub. No.: US 2026/0352220 A1
(43) Pub. Date: Nov. 5, 2026

(54) PHASE LOCKED LOOP SYSTEM AND METHOD FOR TUNING OSCILLATOR

(71) Applicant: Telefonaktiebolaget LM Ericsson (publ), Stockholm (SE)

(72) Inventors: Mohammed ABDULAZIZ, Lund (SE); Henrik SJÖLAND, Lund (SE)

(21) Appl. No.: 19/487,030

(22) PCT Filed: May 30, 2023
(86) PCT No.: PCT/EP2023/064415

§ 371 Date: Nov. 24, 2025

(51) Int. Cl. H03L 7/189; H03L 7/093; H03L 7/099

(52) U.S. Cl. CPC H03L 7/189; H03L 7/093; H03L 7/099

(57) ABSTRACT

A PLL system and method therein for tuning a VCO are disclosed. The PLL includes a VCO, a R-DAC, a digital phase detector, a first adjusting unit, a loop filter, a second adjusting unit and a digital processing unit. The digital processing unit is configured to generate a first and second setting values (DAC_{S1}, DAC_{S2}) for setting a first and a second reference voltages (Vref1, Vref2) to the R-DAC, respectively. The digital processing unit is further configured generate a first correction value (α) for adjusting an output signal (Φₑ) of the digital phase detector and generate a second correction value (β) for adjusting a digital output signal (OTW) of the loop filter in response to a change of one or both of the first and second setting values.

### TECHNICAL FIELD

Embodiments herein relate to Phase Locked Loop (PLL) system. In particular, they relate to PLL system, method for tuning oscillator comprised in the PLL system, transceivers and electronic apparatus comprising the PLL system.

### BACKGROUND

There is a need for accurate local oscillator (LO) signals in wireless transceivers. This is also the case for multi-antenna transceivers that will be used in the 5^{th} and 6^{th} generation (5G/6G) communication systems. Multiple transceivers are usually integrated on a chip. There will be challenges to supply the multiple transceivers at different locations on the same chip with high spectral purity phase coherent LO signals. Operating frequencies of the multiple transceivers are also foreseen to increase, making it increasingly difficult to achieve sufficiently low phase noise on LO signals.

Typically, LO signals are generated using phase locked loops (PLLs). Traditionally analog PLLs have been used, but lately also digital ones. Currently both options are viable, with different pros and cons. A digital PLL (DPLL) has advantages in the absence of an analog loop filter with large area capacitors, and possibility to support advanced digital algorithms to, for instance, speed up frequency hops. An analog PLL on the other hand is much less complex to design and may have excellent performance regarding phase noise. For instance, at very high frequencies or for very low power, the simplicity of an analog PLL makes it an excellent choice. Choosing an analog PLL, however, the possibilities of using digital algorithms to achieve improved performance may be sacrificed. Regardless of using an analog or digital PLL, a key concern is how to achieve sufficiently low phase noise with limited power consumption and chip area, without sacrificing any other aspect. A DPLL with such properties is very much desirable and still a new area to investigate.

For PLLs operating at millimetre wave (mmWave) frequency band with e.g. 30-300 GHz, or operating at sub-terahertz (sub-THz) with e.g. 90 GHz and 300 GHz frequency band, the design of a digitally controlled oscillator (DCO) is very challenging. The switches are lossy and the quantization noise from the DCO becomes dominant even in advanced technology nodes, such as 65 nm, 40 nm, 28 nm, 16 nm etc. semiconductor process technology. The DCO phase noise due to quantization is given by:

$${L}_{tdc} = \frac{1}{12} \cdot {( \frac{Δ {f}_{res}}{offset} )}^{2} \cdot \frac{1}{{F}_{R E F}} \cdot {( sinc \frac{offset}{{F}_{R E F}} )}^{2} \qquad ( 1 )$$

Where Δfᵣₑₛ is the DCO resolution, offset is the frequency offset and F_{REF} is the reference frequency. Interesting to see that the quantization noise is not related to the DCO frequency, and this means that increasing the operating frequency does not necessarily relax the required resolution. With a high reference frequency for such PLLs, e.g. in the order of 5 to 10 GHz for a sub-THz PLL, using a delta-sigma (ΣΔ) modulator to improve the DCO resolution becomes very costly. Let alone that designing a DCO at frequencies above 100 GHz is extremely challenging.

The possibility of combining the benefits of digital and analog PLLs has been exploited at lower frequency ranges to improve phase detection performance, such as in Z. Xu, et. al., “A 3.6 GHz Low-Noise Fractional-N Digital PLL Using SAR-ADC-Based TDC”, IEEE Journal of Solid-State Circuits, vol. 51, no. 10, pp. 2345-2356 October 2016, and in T. Siriburanon et. al., “A 2.2 GHZ-242 dB-FOM 4.2 mW ADC-PLL Using Digital Sub-Sampling Architecture,” IEEE Journal of Solid-State Circuits, vol. 51, no. 6, pp. 1385-1397, June 2016. The DCO quantization noise at low GHz range is mitigated using ΣΔ modulators and the dominant quantization noise source is then that of time to digital converter (TDC). It has been widely accepted that for mmWAVE PLLs an analog approach is favorable. An attempt to make an all-digital PLL at an output frequency of ~80 to 107 GHz is reported in Z. Huang and H. C. Luong, “An 82-107.6-GHz Integer-N ADPLL Employing a DCO With Split Transformer and Dual-Path Switched-Capacitor Ladder and a Clock-Skew-Sampling Delta-Sigma TDC,” IEEE Journal of Solid-State Circuits, vol. 54, no. 2, pp. 358-367, February 2019. However, the design of the DCO is complex resulting in an overall complex DPLL architecture. Due to high varactor parasitic and unpractical inductor size, complex transformer tuning structures were proposed.

### SUMMARY

Therefor it is an object of embodiments herein to provide a Phase Locked Loop (PLL) system with improved performance.

According to a first aspect of embodiments herein, the object is achieved by a Phase Locked Loop (PLL) system. The PLL system comprises a voltage controlled oscillator (VCO) configured to generate an output signal Out, a Resistive Digital to Analog Converter (R-DAC) configured to receive a first reference voltage Vref1 and a second reference voltage Vref2 and a digital input signal OTW_{DAC}, and generate a control signal Vctrl to the VCO to adjust the frequency of the output signal generated by the VCO. The first and second reference voltages are programmable and define an output range of the R-DAC.

The PLL system further comprises a digital phase detector configured to receive a reference signal Ref and a feedback signal FB to generate an output signal Øe representing a frequency or phase difference between the reference and feedback signals. The feedback signal FB is generated based on the output signal Out from the VCO.

The PLL system further comprises a first adjusting unit configured to adjust the output signal φe of the digital phase detector by a first correction value α to produce an adjusted output signal φe′ of the digital phase detector.

The PLL system further comprises a loop filter configured to receive the adjusted output signal φe′ of the digital phase detector and generate a digital output signal OTW.

The PLL system further comprises a second adjusting unit configured to adjust the digital output signal OTW of the loop filter by a second correction value β to produce the digital input signal OTW_{DAC} to the R-DAC.

The PLL system further comprises a digital processing unit configured to, based on the digital input signal OTW_{DAC} to the R-DAC, generate a first and second setting values DAC_{S1}, DAC_{S2} for setting the first and second reference voltages Vref1, Vref2 respectively, generate the first correction value α for adjusting the output signal φe of the digital phase detector in response to a change of one or both of the first and second setting values DAC_{S1}, DAC_{S2}, and generate the second correction value β for adjusting the digital output signal OTW of the loop filter in response to a change of one or both of the first and second setting values DAC_{S1}, DAC_{S2}.

According to some embodiments herein, the PLL system may further comprise a first reference voltage generating circuit and a second reference voltage generating circuit configured to generate the first and second reference voltages Vref1, Vref2 based on the first and second setting values DAC_{S1}, DAC_{S2} respectively. Each reference voltage generating circuit comprises a DAC.

According to some embodiments herein, the digital processing unit may be configured to generate the first and second setting values DAC_{S1}, DAC_{S2} to set the first and second reference voltages Vref1, Vref2 such that the R-DAC operates in a first output range, e.g. a full output range, during a starting stage of the PLL system.

According to some embodiments herein, the digital processing unit may be configured to generate the first and second setting values DAC_{S1}, DAC_{S2} such that the first and second reference voltages Vref1, Vref2 are changed stepwise during a lock stage of the PLL system.

According to some embodiments herein, the digital processing unit may be configured to determine a second output range of the R-DAC, i.e. a final output range of the R-DAC after the stepwise changes of the first and second reference voltages Vref1, Vref2, determine a number of steps K1, K2 for each of the first and second reference voltages Vref1, Vref2 to be changed stepwise, determine a number of clock cycles for each of the first and second reference voltages to be kept at each step and determine if the PLL system is in a lock stage by monitoring the value of the control signal Vctrl to the VCO or the value of the digital input signal (OTW_{DAC}) to the R-DAC. When the PLL system is in the lock stage, the digital processing unit may be configured to calculate a step size value for each of the first and second reference voltages Vref1, Vref2 based on the number of steps, the second output range of the R-DAC and the value of the control signal Vctrl to the VCO, and generate a first and a second setting values DAC_{S1}, DAC_{S2} based on the step size values to set the first and second reference voltages Vref1, Vref2.

In other words, some embodiments herein provide a PLL system with a VCO. A digital phase detector e.g. a TDC may be used. The control voltage to the VCO is generated by an R-DAC, which receives its two reference voltages Vref1, Vref2 from two other DACs. When the two reference voltages Vref1, Vref2 are set close to each other, the R-DAC will present a high resolution, which will be the case in a steady state condition, i.e. when the PLL is locked. The procedure to achieve the steady state may be that, firstly the two reference voltages Vref1, Vref2 may be set wide apart so the R-DAC operates in a first output range, e.g. the full output range, and can control the VCO over a wide frequency range, i.e. the R-DAC has high gain, and allow the PLL system to approach lock. The high gain of the R-DAC will require a reduced gain of the rest of the loop to maintain the bandwidth, so the output signal φₑ of the digital phase detector may be adjusted by a first correction value α to maintain the loop gain. When the lock has been approached, the digital input value of the R-DAC may be used to determine stepwise changes to the first and second reference voltages Vref1, Vref2, that will result in an R-DAC input which is close to the center of the R-DAC range, and the R-DAC will then output a control voltage near its mid value, i.e. the final R-DAC input being centered, and the first and second reference voltages Vref1, Vref2 being close enough for a sufficient oscillator control resolution. As the first and second reference voltages Vref1, Vref2 are brought closer, the gain of the rest of the loop (except for the R-DAC) may be reduced to maintain the PLL bandwidth, and a new first correction value α may be calculated. At the same time the R-DAC input will approach the mid-scale value, and in order not to disturb the PLL phase, a suitable second correction value β may be calculated so that the loop does not have to respond, i.e. the control signal Vctrl is maintained without any changes in φe. The calculation of the first and second reference voltages Vref1, Vref2, as well as the first and second correction values α and β may be performed by the processing unit.

According to a second of embodiments herein, the object is achieved by a method performed in a PLL system for generating an output signal Out.

The method comprises generating the output signal Out by a voltage controlled oscillator (VCO); generating by a Resistive Digital to Analog Converter (R-DAC), a control signal Vctrl to the VCO to adjust the frequency of the output signal Out generated by the VCO, the R-DAC is configured to receive a first and a second reference voltages Vref1, Vref2 and a digital input signal OTW_{DAC}, the first and second reference voltages are programmable and define an output range of the R-DAC; generating by a digital processing unit, a first and a second setting values DAC_{S1}, DAC_{S2} for setting the first and second reference voltages Vref1, Vref2 respectively based on the digital input signal OTW_{DAC} to the R-DAC; generating a feedback signal FB based on the output signal Out from the DCO; generating an output signal φₑ representing a frequency or phase difference between the reference and feedback signals by a digital phase detector configured to receive a reference signal Ref and the feedback signal; generating by the digital processing unit, a first correction value α for adjusting the output signal φₑ of the digital phase detector in response to a change of one or both of the first and second setting values; adjusting the output signal φₑ of the digital phase detector by the first correction value α in a first adjusting unit to produce an adjusted output signal φₑ′ of the digital phase detector; generating a digital output signal OTW by a loop filter configured to receive the adjusted output signal φₑ′ of the digital phase detector; generating by the digital processing unit, a second correction value β for adjusting the digital output signal OTW of the loop filter in response to a change of one or both of the first and second setting values; and adjusting the digital output signal OTW of the loop filter by the second correction value β in a second adjusting unit 181 to produce the digital input signal OTW_{DAC} to the R-DAC.

According to a third aspect of embodiments herein, the object is achieved by a method performed in the PLL system described above for tuning a frequency of the output signal of the PLL system.

The method comprises generating a first and second setting values DAC_{S1}, DAC_{S2} to set the first and second reference voltages Vref1, Vref2 such that the R-DAC is in a first output range, a full range, during a starting stage of the PLL system; determining if the PLL system is in a lock stage by monitoring the value of the control signal Vctrl to the VCO or the digital input signal OTW_{DAC} value to the R-DAC 120; When the PLL system is in the lock stage, determining a second output range, i.e. a final output range of the R-DAC after stepwise changes of the first and second reference voltages Vref1, Vref2; determining a number of steps K1, K2 for each of the first and second reference voltages Vref1, Vref2 to be changed stepwise; determining a number of clock cycles for each of the first and second reference voltages to be kept at each step; calculating a step size value for each of the first and second reference voltages Vref1, Vref2 based on the number of steps, the second output range of the R-DAC and the value of the control signal Vctrl to the VCO; and for each step k, k=1, 2 . . . . K1/K2, generating a first and a second setting values DAC_{S1}, DAC_{S2} based on the step size values to set the first and second reference voltages Vref1, Vref2; calculating a first correction value α based on a difference between the first and second reference voltages Vref1, Vref2 at the k-th step; adjusting the output signal φₑ of the digital phase detector by the first correction value α; calculating a second correction value β based on the second correction value at the (k−1)-th step, the first output range of the R-DAC, the first and second reference voltages Vref1, Vref2 at the (k−1)-th and k-th steps, and the value of the digital input signal OTW_{DAC} to the R-DAC at (k−1)-th step; adjusting the digital output signal OTW of the loop filter 180 by the second correction value β to produce the digital input signal OTW_{DAC} to the R-DAC; and generating by the R-DAC, a control signal Vctrl to the VCO based on the digital input signal OTW_{DAC} to tune the frequency of the output signal Out generated by the VCO.

Embodiments herein provide a digital PLL with a VCO controlled by an R-DAC. The reference voltages of the R-DAC are programmable. The reference voltage range to the R-DAC is set such that the R-DAC is at the full output range when the PLL is in the starting stage, and then during the lock stage, the reference voltage range is progressively reducing, while performing loop compensation by the first and second correction values, both multiplicative to maintain PLL bandwidth and additive not to disturb the PLL phase.

The PLL system and method according to embodiment herein have some advantages, for examples:

Enabling a simple high frequency VCO implemented in a digital PLL and providing an easy interface to off-chip VCOs thanks to R-DAC.

Simple and continuous implementation of gear changes for the control signal to the VCO, in contrast to using several different capacitor banks in DCOs, the difference between the first and second reference voltages can be tuned which results in easy locking procedure.

The filters needed to generate low noise R-DAC reference voltages can be shared between multiple PLLs operating at the same output frequency to save chip area, in contrast to loop filters in analog PLLs, which must be individual.

Enabling the use of digital loops and algorithms, e.g. for multi-input-multi-output (MIMO) systems while using a simple VCO which is easy to implement.

Therefore, the embodiments herein provide an improved PLL system with regard to, e.g. locking performance, size, cost, implementations etc.

### BRIEF DESCRIPTION OF THE DRAWINGS

Examples of embodiments herein are described in more detail with reference to attached drawings in which:

FIG. 1 is a schematic block view of a PLL circuit according to embodiments herein;

FIG. 2 is a schematic block view of a R-DAC according to embodiments herein

FIGS. 3 (a) and (b) are diagrams illustrating stepwise changing of the reference voltages and changes of the correction values according to embodiments herein;

FIG. 4 is a schematic block view illustrating an example reference voltage generating circuit according to embodiments herein;

FIG. 5 is a schematic block view illustrating an example reference voltage generating circuit according to embodiments herein;

FIG. 6 is a schematic block view illustrating an example reference voltage generating circuit according to embodiments herein;

FIG. 7 is a schematic block view illustrating an example of VCO;

FIG. 8 is a flow chart illustrating a method performed by the PLL system according to embodiments herein;

FIG. 9 is a flow chart illustrating a method performed by the PLL system according to embodiments herein;

FIG. 10 is a schematic block view illustrating function units of a digital processing unit according to embodiments herein; and

FIG. 11 is a block diagram illustrating an electronic device in which a PLL system according to embodiments herein may be implemented.

### DETAILED DESCRIPTION

In order to take the benefits from both digital and analog PLLs, embodiments herein provide a digital PLL with a VCO controlled by an R-DAC. The R-DAC has a first and second reference voltages which are programmable.

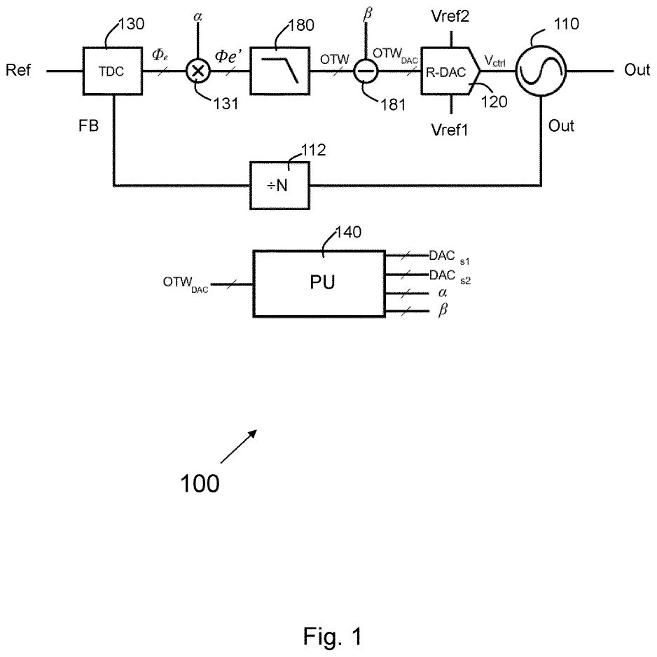

FIG. 1 is a schematic block diagram showing a PLL system 100 according to embodiments herein. The PLL system 100 comprises a VCO 110 configured to generate an output signal Out.

The PLL system 100 further comprises a Resistive Digital to Analog Converter R-DAC 120, configured to receive a first reference voltage Vref1 and a second reference voltage Vref2 and a digital input signal OTW_{DAC}, and generate a control signal Vctrl to the VCO 110 to adjust the frequency of the output signal Out generated by the VCO 110. The first and second reference voltages Vref1, Vref2 are programmable and define an output range of the R-DAC.

The PLL system 100 further comprises a digital phase detector 130 configured to receive a reference signal Ref and a feedback signal FB to generate an output signal φe representing a frequency or phase difference between the reference and feedback signals. The feedback signal FB is generated based on the output signal Out from the VCO, e.g. by dividing the output signal Out in a divider by N 112.

The PLL system 100 further comprises a first adjusting unit 131 configured to adjust the output signal φe of the digital phase detector 130 by a first correction value α to produce an adjusted output signal φe′ of the digital phase detector 130.

The PLL system 100 further comprises a loop filter 180 configured to receive the adjusted output signal φe′ of the digital phase detector 130 and generate a digital output signal OTW.

The PLL system 100 further comprises a second adjusting unit 181 configured to adjust the digital output signal OTW of the loop filter 180 by a second correction value β to produce the digital input signal OTW_{DAC} to the R-DAC 120.

The PLL system 100 further comprises a digital processing unit 140 configured to, based on the digital input signal OTW_{DAC} to the R-DAC 120, generate a first and second setting values DAC_{S1}, DAC_{S2} for setting the first and second reference voltages Vref1, Vref2 respectively, generate the first correction value α for adjusting the output signal de of the digital phase detector 130 in response to a change of one or both of the first and second setting values DAC_{S1}, DAC_{S2}, and generate the second correction value β for adjusting the digital output signal OTW of the loop filter 180 in response to a change of one or both of the first and second setting values DAC_{S1}, DAC_{S2}.

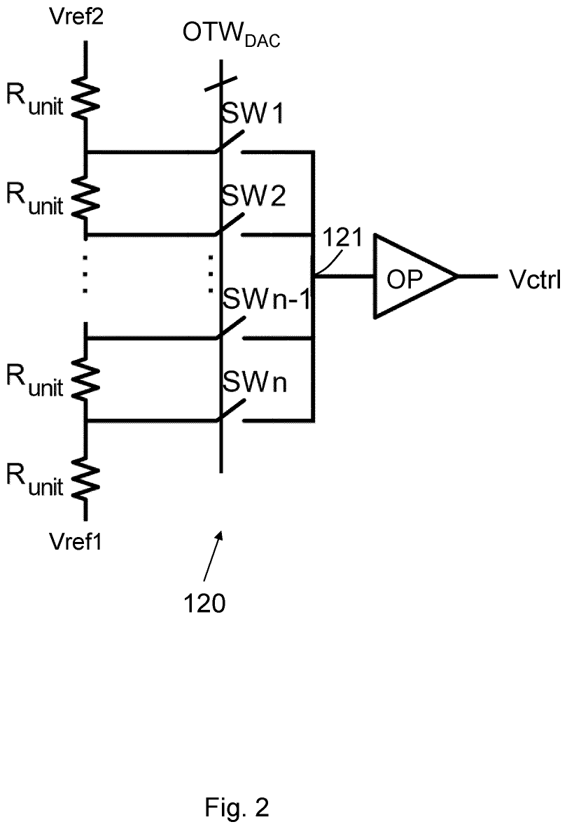

FIG. 2 is a schematic block diagram showing an example of the R-DAC 120. As can be seen, the R-DAC 120 comprises a resistor chain comprising a number of resistors Rᵤₙᵢₜ connected in series. The first and second reference voltages Vref1, Vref2 are applied at two ends of the resistor chain. The R-DAC 120 further comprises a number of switches SW1, SW2, . . . . SWn−1, SWn. One terminals of the switches SW1, SW2, . . . . SWn−1, SWn are respectively connected to a connecting node between two resistors, other terminals of the switches SW1, SW2, . . . . SWn−1, SWn are connected together to an output node 121 and then to a voltage buffer, e.g. an optional amplifier OP configured to generate the control signal Vctrl. The switches SW1, SW2, . . . . SWn−1, SWn are controlled by the digital input signal OTW_{DAC} to provide various voltage levels to the optional amplifier OP to generate the control signal Vctrl with various voltage levels. The optional amplifier OP may be omitted, so the control signal Vctrl with various voltage levels may be provided directly from the output node 121 of the R-DAC 120.

The first and second reference voltages Vref1, Vref2 to the R-DAC 120 are programmable and define an output range of the R-DAC. The first and second setting values DAC_{S1}, DAC_{S2} are for setting the first and second reference voltages Vref1, Vref2 respectively.

In principle operating the PLL system 100 will start by setting the first and second reference voltages Vref1, Vref2 of the R-DAC 120 to a maximum and minimum voltage level respectively, e.g. the maximum supply voltage and ground, so that the output range of the R-DAC 120 is in a full output range, i.e. the maximum output range the R-DAC 120 supports or operates. That is the R-DAC 120 is in rail to rail operation. Progressively detecting Vctrl settling, i.e. the R-DAC input value OTW_{DAC}, is then required to detect if the PLL is locked. Once the loop is settled or locked, the first and second reference voltages Vref1, Vref2 to the R-DAC 120 are changed stepwise in several steps. The settled value for Vctrl, i.e. the digital signal input OTW_{DAC} value is used to calculate how the first and second reference voltages Vref1, Vref2 should be stepped.

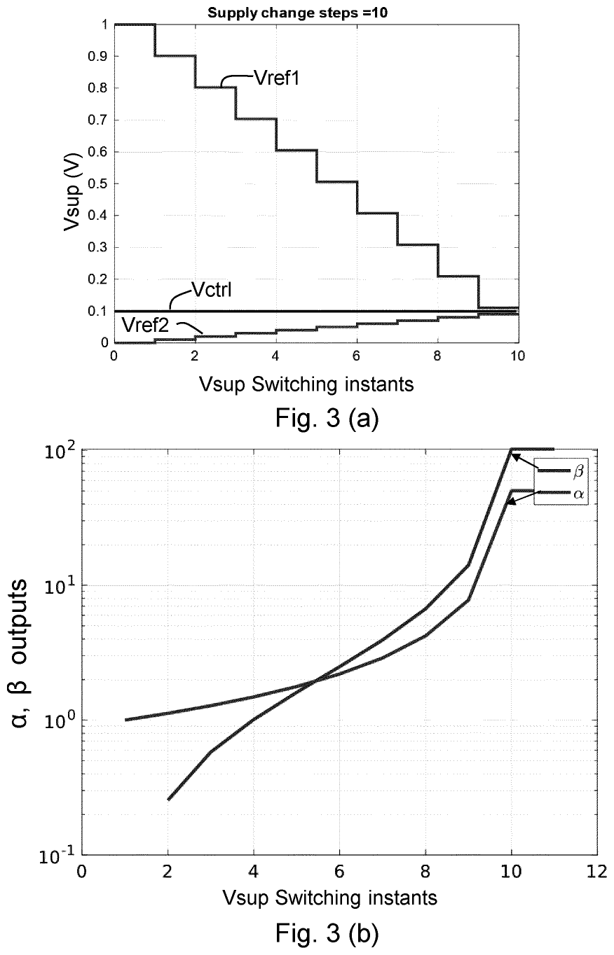

An example is shown in FIG. 3 (a), where the stepping is performed from 1 V to 20 mV DAC range in 10 steps. In the figure Vctrl is assumed to settle to 0.1 V. Based on that, Vref2 is stepped down from 1 V to 0.11 V in steps of 0.0989 V, while Vref2 is stepped up in steps of 10 mV. The end value for Vref2 is 0.11 V, and for Vref1 it is 0.09 V. The linear steps in the first and second reference voltages in this example is just one option, the step sizes may also be different from step to step, with larger steps initially and smaller towards the end. The first and second correction values α and β for the loop gain and bandwidth corrections are shown in FIG. 3 (b).

Therefore, according to some embodiments herein, the digital processing unit 140 may be configured to generate the first and second setting values DAC_{S1}, DAC_{S2} to set the first and second reference voltages Vref1, Vref2 such that the R-DAC 120 operates or is in a first output range, e.g. the full output range or maximum output range of the R-DAC, during a starting stage of the PLL system 100.

According to some embodiments herein, the digital processing unit 140 may further be configured to generate the first and second setting values DAC_{S1}, DAC_{S2} such that the first and second reference voltages Vref1, Vref2 are changed stepwise during a lock stage of the PLL system 100.

To achieve stepwise changing the first and second reference voltages Vref1, Vref2 during the lock stage, the digital processing unit 140 may be configured to determine a second output range of the R-DAC 120, i.e. a final output range of the R-DAC after stepwise changes of the first and second reference voltages Vref1, Vref2, determine a number of steps K1, K2 for each of the first and second reference voltages Vref1, Vref2 to be changed stepwise towards the first and second reference voltages defining the second output range of the R-DAC 120 and determine a number of clock cycles for each of the first and second reference voltages to be kept at each step.

The digital processing unit 140 may be further configured to determine if the PLL system 100 is in the lock stage by monitoring the digital input signal OTW_{DAC} value or the value of the control signal Vctrl to the VCO 110. For example, if the variation of Vctrl is within a voltage range, e.g. 0.09 V<Vctrl<0.11 V or the digital input signal OTW_{DAC} is stable or within a digital word range, the PLL is in the lock stage. The stability of the digital input signal OTW_{DAC} may be determined by calculating an average over a time interval and then determine if the maximum deviation from that average in the interval is within a threshold.

Or take the difference between the maximum and minimum values over the interval, and then determine if the difference in the interval is within a threshold. Another example may be to calculate different measures of the deviation from the average, e.g. the mean square, also known as variance and determine if the measures of the deviation is within a threshold.

When the PLL system 100 is in the lock stage, the digital processing unit 140 is configured to calculate a step size value for each of the first and second reference voltages Vref1, Vref2 based on the number of steps, the second output range of the R-DAC 120 and the value of the control signal Vctrl to the VCO 110. For examples, the step size values for the first and second reference voltages may be calculated as:
Vref1 Step up=(V_{CTRL}−DAC range/2)/number of steps K1
Vref2 Step down=(1−DAC range/2+V_{CTRL})/number of steps K2

The linear steps in the first and reference voltages in this calculation example are just one option, the step sizes may also be different from step to step, with larger steps initially and smaller towards the end.

For each step k, k=1, 2 . . . . K1/K2, the digital processing unit 140 is configured to calculate the first correction value α based on a difference between the first and second reference voltages Vref1, Vref2 at the k-th step Vref1(k), Vref2(k) and calculate the second correction value β based on the second correction value at the (k−1)-th step β(k−1), the first output range, i.e. the full output range, of the R-DAC fullscale, the first and second reference voltages Vref1, Vref2 at the (k−1)-th and k-th steps Vref1(k−1), Vref2(k−1), Vref1(k), Vref2(k) and the value of the digital input signal OTW_{DAC} to the R-DAC (120) at (k−1)-th step DACinput(k−1), for examples according to the following equations:

α(k)=1/(Vref1(k)−Vref2(k))

deltaY2=Vref2(k−1)−Vref2(k)

deltaY1=Vref1(k)−Vref1(k−1)

DACinput(k−1)=fullscale*(Vctrl−Vref2(k−1))/(Vref1(k−1)−Vref2(k−1));

β(k)=β(k−1)+fullscale*(deltaY2*(1−DACinput(k−1)/fullscale)−deltaY1*DACinput(k−1)/fullscale)/(deltaY2+deltaY1+Vref1(k−1)−Vref2(k−1))

The digital processing unit 140 is configured to generate the first and second setting values DAC_{S1}, DAC_{S2} according to the step size values for the first and second reference voltages and generate the first and second correction values α and β for each step until the first and second reference voltages are set such that the final output range of R-DAC is reached.

According to some embodiments herein, the first adjusting unit 131 may be configured to adjust the output signal φₑ of the digital phase detector 130 by multiplying the output signal φₑ of the digital phase detector 130 with the first correction value α or by dividing the output signal φₑ of the digital phase detector 130 by the reciprocal of the first correction value, i.e. a correction value equal to 1/α, where α is the first correction value as calculated from the equations above.

According to some embodiments herein, the second adjusting unit 181 may be configured to adjust the digital output signal OTW of the loop filter 180 by subtracting the second correction value β from the digital output signal OTW or by adding the negation of the second correction value, i.e. a correction value equal to −β, to the digital output signal OTW, where β is the second correction value as calculated from the equations above.

The first and second reference voltages Vref1, Vref2 need to be low noise. There are number of ways to generate the first and second reference voltages Vref1, Vref2 with low noise.

According to some embodiments herein, the PLL system 100 may further comprise a first reference voltage generating circuit and a second reference voltage generating circuit configured to generate the first and second reference voltages Vref1, Vref2 based on the first and second setting values DAC_{S1}, DAC_{S2} respectively.

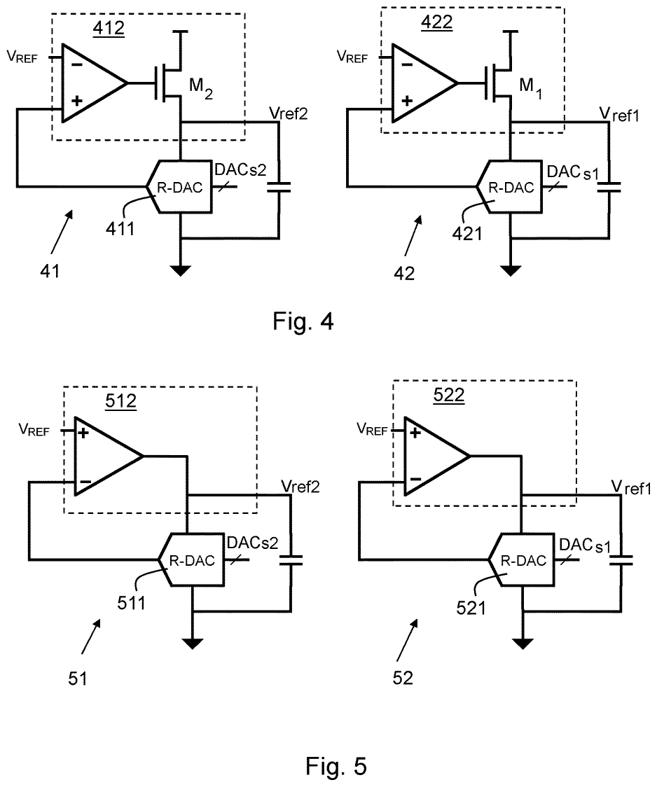

FIG. 4 shows an example of the first and second reference voltage generating circuits 41, 42. Each reference voltage generating circuit 41, 42 may comprise a DAC 411, 421 which may be an R-DAC, a low drop-out regulator (LDO) 412, 422. The first and second setting values DAC_{S1}, DAC_{S2} control the DAC 411, 421 to generate the desired first and second reference voltages Vref1, Vref2. Unlike the R-DAC 120 shown in FIG. 2, the resistors in the R-DAC 411, 421 used in the first and second reference voltage generating circuits 41, 42 may be designed with unequal sizes to compensate some non-linearity due to having the R-DAC in the feedback path and make the overall DAC_{S1} and DAC_{S2} to reference voltage characteristic more linear.

A low value of an input reference VREF can be used for the LDO 412, 422, and the feedback path comprising the DAC 411, 421 control the amplification of this input reference voltage based on the DAC setting values DAC_{S1}, DAC_{S2}. For a certain frequency tuning characteristic of the VCO 110, a suitable value for VREF may be 0.1 V where the VCO 110 gain is compressed. The two LDOs 412, 422 can produce any value from 0.1 to 1V. The disadvantage of this approach is that the noise is also amplified when a high voltage ratio is required.

The transistors M₁, M₂ in the LDO 412, 422 may be omitted which results in a simple implementation for the first and second reference voltage generating circuits.

FIG. 5 shows another example of the first and second reference voltage generating circuits 51, 52. Each reference voltage generating circuit 51, 52 may comprises a DAC 511, 521 which may be a R-DAC and an operational amplifier 512, 522. The first and second setting values DAC_{S1}, DAC_{S2} control the DAC 511, 521 to generate the desired first and second reference voltages Vref1, Vref2.

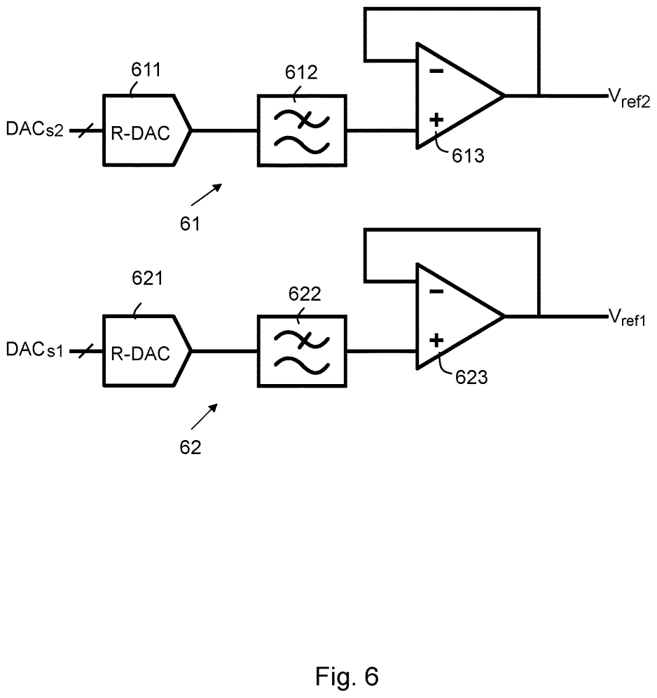

FIG. 6 shows another example of the first and second reference voltage generating circuits 61, 62. Each reference voltage generating circuit 61, 62 comprises a DAC 611, 621 which may be an R-DAC, a low-pass filter 612, 622 used to filter out noise and a voltage buffer 613, 623 used to produce required current. No voltage gain is involved in this solution. The first and second setting values DAC_{S1}, DAC_{S2} control the DAC 611, 621 to generate the desired first and second reference voltages Vref1, Vref2.

The capacitors and filters required in the first and second reference voltage generating circuits to produce clean reference voltages Vref1, Vref2 may be hard to motivate due to chip area occupied by capacitors. However, in a MIMO system the circuits in FIGS. 4-6 may be shared between many PLLs. To prove this, it needs to investigate the mismatch performance of a VCO and check the Vctrl variation for a given frequency, e.g. 120 GHz. To support many PLLs with the same Vref1, Vref2, a variation range of around e.g. 12 mV may be required for Vctrl. For example, if a minimum range of 24 mV is set for Vctrl, a 10-bit R-DAC may give a control voltage resolution of 24e-3/1024=23.4 uV. If the VCO gain is e.g. 11.59 GHZ/V. This means that with 24 mV range on the R-DAC, the frequency resolution would then be equal to or better than 0.27 MHz. This would result in a quantization noise of −118 dBc/Hz at 1 MHz offset with a reference frequency of 5 GHZ, i.e. well below the targeted total noise of e.g. −100 dBc/Hz, providing some margins in this case for relaxed reference voltages and/or reduced R-DAC resolution.

Investigations and simulations have been performed to gain insight into the requirements on the filters in the reference voltage generating circuits and R-DAC and the power consumption of those blocks as well as noise penalty when adding them. The cost is also investigated when considering this solution to be used in a single PLL system, i.e. the filter is not shared. The investigations and simulations result in that the circuits required to implement this proposed PLL system would only consume minimal current, and the filters required to filter noise from the LDOs in the reference generation circuits have a reasonably small chip footprint making it attractive for single PLL system as well.

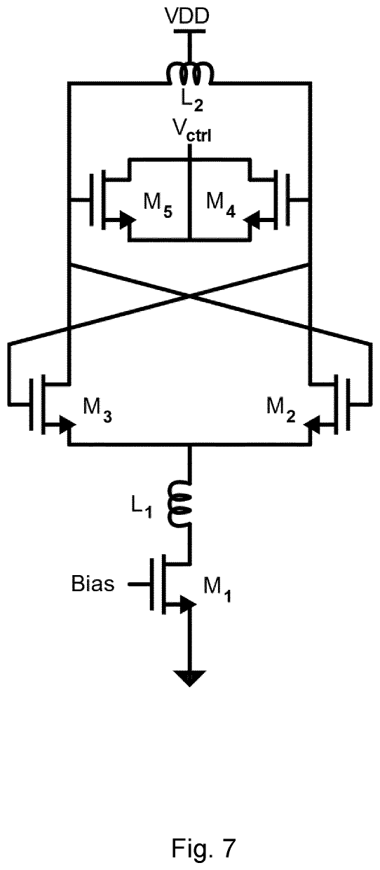

The VCO 110 in the PLL system 100 may be any type of VCO. FIG. 7 is a schematic block diagram showing an example of the VCO 110 implemented in a Complementary metal-oxide-semiconductor (CMOS) process. The VCO 110 in this example comprises two cross-coupled MOS transistors M₂, M₃, the control voltage Vctrl is applied to two MOS transistor M₅, M₄ working as varactors, i.e. voltage-controlled capacitors so that the capacitance of the MOS transistor M₅, M₄ is changed in response to the control voltage Vctrl and thereby the frequency of the VCO is changed. Inductor L2 is a differential inductor resonating with the capacitances of the two MOS transistor M₅, M₄ and other capacitances present at these nodes, like parasitic capacitances of M2 and M3, routing wire parasitic capacitances, and input capacitance of the following stage, typically a buffer etc. Transistor M₁ and inductor L₁ are for biasing the VCO 110, where L1 is inserted to increase the second harmonic frequency impedance of the cross-coupled MOS transistors source node to reduce the oscillator phase noise.

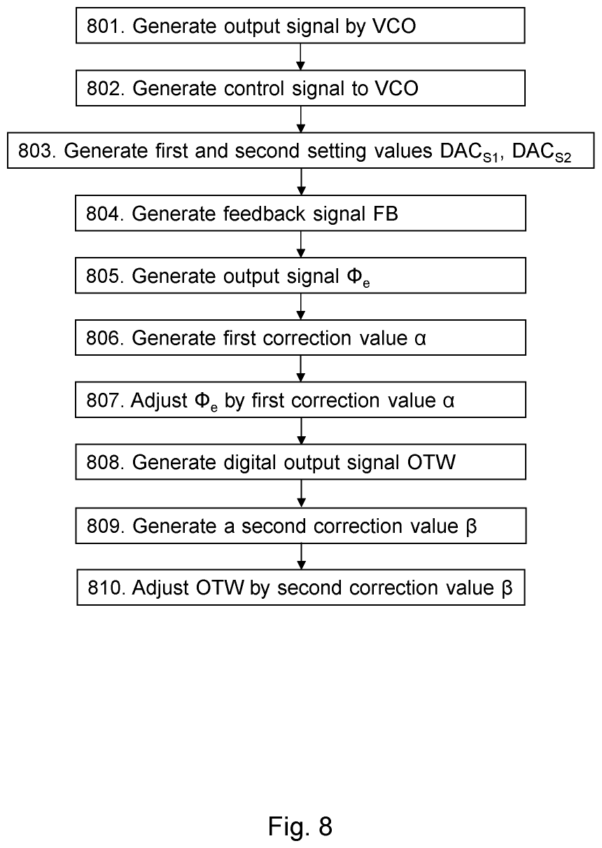

According to one embodiment herein, a method performed in the PLL circuit 100 shown in FIG. 1 for generating an output signal will be described with reference to FIG. 8. The method comprises the following actions which may be performed in any suitable order or simultaneously.

### Action 801

Generating an output signal Out by the VCO 110.

### Action 802

Generating by the R-DAC 120, a control signal Vctrl to the VCO 110 to adjust the frequency of the output signal Out generated by the VCO 110. The R-DAC 120 is configured to receive the first and second reference voltages Vref1, Vref2 and the digital input signal OTW_{DAC}. The first and second reference voltages are programmable and define an output range of the R-DAC 120.

### Action 803

Generating by the digital processing unit 140, a first and a second setting values DAC_{S1}, DAC_{S2} for setting the first and second reference voltages Vref1, Vref2 respectively based on the digital input signal OTW_{DAC} to the R-DAC 120.

### Action 804

Generating a feedback signal FB based on the output signal Out from the VCO 110.

### Action 805

Generating an output signal We by the digital phase detector 130. The digital phase detector 130 is configured to receive a reference signal Ref and the feedback signal FB, and the output signal φₑ represents a frequency or phase difference between the reference and feedback signals.

### Action 806

Generating by the digital processing unit 140, a first correction value α for adjusting the output signal φₑ of the digital phase detector 130 in response to a change of one or both of the first and second setting values DAC_{S1}, DAC_{S2}.

### Action 807

Adjusting the output signal de of the digital phase detector 130 by the first correction value α in the first adjusting unit 131 to produce an adjusted output signal φₑ′ of the digital phase detector 130.

### Action 808

Generating a digital output signal OTW by the loop filter 180 configured to receive the adjusted output signal φₑ′ of the digital phase detector 130.

### Action 809

Generating by the digital processing unit 140, a second correction value β for adjusting the digital output signal OTW of the loop filter 180 in response to a change of one or both of the first and second setting values DAC_{S1}, DAC_{S2}.

### Action 810

Adjusting the digital output signal OTW of the loop filter 180 by the second correction value β in the second adjusting unit 181 to produce the digital input signal OTW_{DAC} to the R-DAC 120.

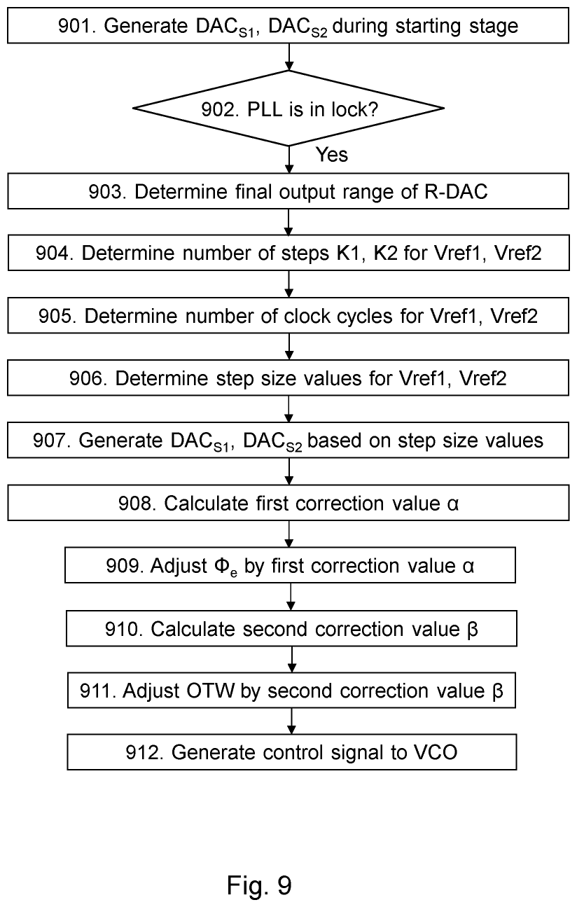

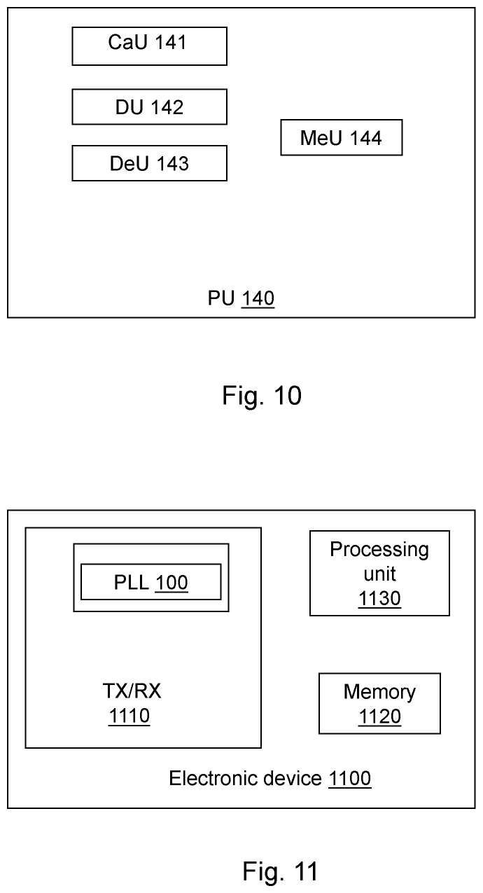

According to one embodiment herein, a method performed in the PLL system 100 shown in FIG. 1 for tuning a frequency of an output signal of the PLL system 100 will be described with reference to FIGS. 9 and 10. FIG. 9 is a flow chart of the method performed in the PLL system 100, FIG. 10 is a block diagram illustrating functional units of the process unit PU 140. The PU 140 may comprise a calculating unit CaU 141, a determining unit DU 142, a detecting unit DeU 143, a memory unit MeU 144 etc.

The method comprises the following actions which may be performed in any suitable order or simultaneously.

### Action 901

The digital processing unit 140 generates, e.g. by means of the calculating unit CaU 141 being configured to, a first and second setting values DAC_{S1}, DAC_{S2} to set the first and second reference voltages Vref1, Vref2 so that the output range of the R-DAC 120 is in a first output range, e.g. a full output range, during a starting stage of the PLL system 100.

### Action 902

The digital processing unit 140 determines, e.g. by means of the determining unit DU 142 or detecting unit DeU 143 being configured to, if the PLL system 100 is in a lock stage by monitoring the value of the control signal Vctrl to the VCO 110 or the digital input signal OTW_{DAC} value to the R-DAC 120.

### Action 903

When the PLL system 100 is locked, the digital processing unit 140 determines, e.g. by means of the determining unit DU 142 being configured to, a second output range of the R-DAC 120, i.e. the final output range of the R-DAC after stepwise changes of the first and second reference voltages Vref1, Vref2.

### Action 904

The digital processing unit 140 determines, e.g. by means of the calculating unit CaU 141 being configured to, a number of steps K1, K2 for each of the first and second reference voltages Vref1, Vref2 to be changed stepwise.

### Action 905

The digital processing unit 140 determines, e.g. by means of the calculating unit CaU 141 being configured to, a number of clock cycles for each of the first and second reference voltages Vref1, Vref2 to be kept at each step.

### Action 906

The digital processing unit 140 calculates, e.g. by means of the calculating unit CaU 141 being configured to, a step size value for each of the first and second reference voltages Vref1, Vref2 based on the number of steps K1, K2, the second output range of the R-DAC 120 and the value of the control signal Vctrl to the VCO 110.

For each step k, k=1, 2 . . . . K1/K2, the method comprises the following actions.

### Action 907

The digital processing unit 140 generates, e.g. by means of the calculating unit CaU 141 being configured to, a first and a second setting values DAC_{S1}, DAC_{S2} based on the step size values to set the first and second reference voltages Vref1, Vref2 so that the first and second reference voltages Vref1, Vref2 are changed stepwise.

### Action 908

The digital processing unit 140 calculates, e.g. by means of the calculating unit CaU 141 being configured to, a first correction value α based on a difference between the first and second reference voltages Vref1, Vref2 at the k-th step Vref1(k), Vref2(k), as α(k)=1/(Vref1(k)−Vref2(k)).

### Action 909

The first adjusting unit 131 adjust the output signal φₑ of the digital phase detector 130 by the first correction value α.

### Action 910

The digital processing unit 140 calculates, e.g. by means of the calculating unit CaU 141 being configured to, a second correction value β based on the second correction value at the (k−1)-th step β(k−1), the first output range, i.e. the full output range, of the R-DAC fullscale, the first and second reference voltages Vref1, Vref2 at the (k−1)-th and k-th steps Vref1(k−1), Vref2(k−1), Vref1(k), Vref2(k) and the value of the digital input signal OTW_{DAC} to the R-DAC (120) at (k−1)-th step DACinput(k−1), for examples according to the following equations:

deltaY2=Vref2(k−1)−Vref2(k)

deltaY1=Vref1(k)−Vref1(k−1)

DACinput(k−1)=fullscale*(Vctrl−Vref2(k−1))/(Vref1(k−1)−Vref2(k−1));

β(k)=β(k−1)+fullscale*(deltaY2*(1−DACinput(k−1)/fullscale)−deltaY1*DACinput(k−1)/fullscale)/(deltaY2+deltaY1+Vref1(k−1)−Vref2(k−1))

### Action 911

The second adjusting unit 181 adjust the digital output signal OTW of the loop filter 180 by the second correction value β to produce the digital input signal OTW_{DAC} to the R-DAC 120.

### Action 912

The R-DAC 120 generates a control signal Vctrl to the VCO 110 based on the digital input signal OTW_{DAC} to tune the frequency of the output signal Out generated by the VCO 110.

The flow charts in FIGS. 8 and 9 only show generating the first and second setting values DAC_{S1}, DAC_{S2} and calculating the first and second correction values α, β for one step. The number of steps is dependent on the desired number of the first and second reference voltages switching steps. The generating of the first and second setting values DAC_{S1}, DAC_{S2} and calculating of the first and second correction values α, B are performed for each step until the first and second reference voltages are set such that the final output range of R-DAC is reached.

The PLL system 100 may be employed in various integrated circuits, electronic circuits, communication devices or apparatus. FIG. 11 shows a block diagram for an electronic device 1100 in which the PLL system 100 according to embodiments herein may be implemented. The electronic device 1100 may comprise a receiver or a transmitter or both i.e. a transceiver TX/RX 1110 in which the PLL system 100 according to embodiments herein may be implemented. The electronic device 1100 may comprise other units, where a memory 1120, a processing unit 1130 are shown. The electronic device 1100 may be any one of a base station, a wireless communication device such as a user equipment or a mobile device for a cellular communication system.

The word “comprise” or “comprising”, when used herein, shall be interpreted as non-limiting, i.e. meaning “consist at least of”.

The embodiments herein are not limited to the above described preferred embodiments. Various alternatives, modifications and equivalents may be used. Therefore, the above embodiments should not be taken as limiting the scope of the invention, which is defined by the appended claims.

1. A Phase Locked Loop, PLL, system comprising:
a voltage controlled oscillator, VCO, configured to generate an output signal (Out);
a Resistive Digital to Analog Converter, R-DAC, configured to receive a first reference voltage (Vref1) and a second reference voltage (Vref2) and a digital input signal (OTW_{DAC}), and generate a control signal (Vctrl) to the VCO to adjust the frequency of the output signal (Out) generated by the VCO, the first and second reference voltages being programmable and defining an output range of the R-DAC;
a digital phase detector configured to receive a reference signal (Ref) and a feedback signal (FB) to generate an output signal (Φₑ) representing a frequency or phase difference between the reference and feedback signals, wherein the feedback signal (FB) being generated based on the output signal (Out) from the VCO;
a first adjusting unit configured to adjust the output signal (Φₑ) of the digital phase detector by a first correction value (α) to produce an adjusted output signal (Φₑ′) of the digital phase detector;
a loop filter configured to receive the adjusted output signal (Φₑ′) of the digital phase detector and generate a digital output signal (OTW);
a second adjusting unit configured to adjust the digital output signal (OTW) of the loop filter by a second correction value (β) to produce the digital input signal (OTW_{DAC}) to the R-DAC; and
a digital processing unit configured to, based on the digital input signal (OTW_{DAC}) to the R-DAC:
generate a first and second setting values (DAC_{S1}, DAC_{S2}) for setting the first and second reference voltages (Vref1, Vref2) respectively;
generate the first correction value (α) for adjusting the output signal (Φₑ) of the digital phase detector in response to a change of one or both of the first and second setting values; and
generate the second correction value (β) for adjusting the digital output signal (OTW) of the loop filter in response to a change of one or both of the first and second setting values.

2. The PLL system according to claim 1, further comprising a first reference voltage generating circuit and a second reference voltage generating circuit configured to generate the first and second reference voltages (Vref1, Vref2) based on the first and second setting values (DAC_{S1}, DAC_{S2}) respectively.

3. The PLL system according to claim 2, wherein each reference voltage generating circuit comprises a DAC, a low drop-out regulator, LDO, or each reference voltage generating circuit comprises a DAC and an operational amplifier, or each reference voltage generating circuit comprises a DAC, a low-pass filter and a voltage buffer.

4. The PLL system according to claim 1, wherein the digital processing unit is configured to generate the first and second setting values (DAC_{S1}, DAC_{S2}) to set the first and second reference voltages (Vref1, Vref2) such that the R-DAC operates in a first output range during a starting stage of the PLL system.

5. The PLL system according to claim 4, wherein the digital processing unit is further configured to generate the first and second setting values (DAC_{S1}, DAC_{S2}) such that the first and second reference voltages (Vref1, Vref2) are changed stepwise during a lock stage of the PLL system.

6. The PLL system according to claim 5, wherein the digital processing unit is further configured to:
determine a second output range of the R-DAC;
determine a number of steps (K1, K2) for each of the first and second reference voltages (Vref1, Vref2) to be changed stepwise towards the first and second reference voltages defining the second output range of the R-DAC;
determine a number of clock cycles for each of the first and second reference voltages to be kept at each step.

7. The PLL system according to claim 4, wherein the digital processing unit is further configured to:
determine if the PLL system is in the lock stage by monitoring the value of the control signal (Vctrl) to the VCO or the value of the digital input signal (OTW_{DAC}) to the R-DAC;
when the PLL system is in the lock stage,
calculate a step size value for each of the first and second reference voltages (Vref1, Vref2) based on the number of steps, the second output range of the R-DAC and the value of the control signal (Vctrl) to the VCO; and for each step k, k=1, 2 . . . K1/K2,
generate a first and a second setting values (DAC_{S1}, DAC_{S2}) based on the step size values to set the first and second reference voltages Vref1, Vref2;
calculate the first correction value (α) based on a difference between the first and second reference voltages (Vref1, Vref2) at the k-th step,
calculate the second correction value (β) based on the second correction value at the (k−1)-th step, the first output range of the R-DAC, the first and second reference voltages (Vref1, Vref2) at the (k−1)-th and k-th steps, and the value of the digital input signal (OTW_{DAC}) to the R-DAC at (k−1)-th step.

8. The PLL system according to claim 1, wherein the first adjusting unit is configured to adjust the output signal (Φₑ) of the digital phase detector by multiplying the output signal (Φₑ) of the digital phase detector with the first correction value (α) or by dividing the output signal (Φₑ) of the digital phase detector by the reciprocal of the first correction value (1/α).

9. The PLL system according to claim 1, wherein the second adjusting unit is configured to adjust the digital output signal (OTW) of the loop filter by adding the second correction value (β) to the digital output signal (OTW) or by subtracting the negation of the second correction value (−β) from the digital output signal (OTW).

10. The PLL system according to claim 1, wherein two or more PLL systems are comprised in a transceiver.

11. The PLL system according to claim 1, wherein the PLL system is comprised in an electronic apparatus.

12. The electronic apparatus according to claim 11, wherein the electronic apparatus is a communication apparatus.

13. The electronic apparatus according to claim 12, wherein the communication apparatus is any one of a wireless communication device and a base station for a cellular communications system.

14. A method performed in a Phase Locked Loop, PLL, system for generating an output signal, the method comprising:
generating an output signal (Out) by a voltage controlled oscillator, VCO;
generating by a Resistive Digital to Analog Converter, R-DAC, a control signal (Vctrl) to the VCO to adjust the frequency of the output signal (Out) generated by the VCO, the R-DAC being configured to receive a first and a second reference voltages (Vref1, Vref2) and a digital input signal (OTW_{DAC}), the first and second reference voltages being programmable and defining an output range of the R-DAC;
generating by a digital processing unit, a first and a second setting values (DAC_{S1}, DAC_{S2}) for setting the first and second reference voltages (Vref1, Vref2) respectively based on the digital input signal (OTW_{DAC}) to the R-DAC;
generating a feedback signal (FB) based on the output signal (Out) from the VCO;
generating an output signal (Φₑ) by a digital phase detector, wherein the digital phase detector is configured to receive a reference signal (Ref) and the feedback signal (FB), and the output signal (Φₑ) represents a frequency or phase difference between the reference and feedback signals;
generating by the digital processing unit, a first correction value (α) for adjusting the output signal (Φₑ) of the digital phase detector in response to a change of one or both of the first and second setting values (DAC_{S1}, DAC_{S2});
adjusting the output signal (Φₑ) of the digital phase detector by the first correction value (α) in a first adjusting unit to produce an adjusted output signal (Φₑ′) of the digital phase detector;
generating a digital output signal (OTW) by a loop filter configured to receive the adjusted output signal (Φₑ′) of the digital phase detector;
generating by the digital processing unit, a second correction value (β) for adjusting the digital output signal (OTW) of the loop filter in response to a change of one or both of the first and second setting values (DAC_{S1}, DAC_{S2}); and
adjusting the digital output signal (OTW) of the loop filter by the second correction value (β) in a second adjusting unit to produce the digital input signal (OTW_{DAC}) to the R-DAC.

15. A method performed in a PLL system for tuning a frequency of an output signal of the PLL system, the PLL system comprising:
a voltage controlled oscillator, VCO, configured to generate the output signal (Out);
a Resistive Digital to Analog Converter, R-DAC, configured to receive a first and a second reference voltages (Vref1, Vref2) and a digital input signal (OTW_{DAC}), and generate a control signal (Vctrl) to the VCO to adjust the frequency of the output signal (Out);
a digital phase detector configured to receive a reference signal (Ref) and a feedback signal (FB) to generate an output signal (Φₑ) representing a frequency or phase difference between the reference and feedback signals, the feedback signal being generated based on the output signal (Out) from the VCO;
a first adjusting unit configured to adjust the output signal (Φₑ) of the digital phase detector by a first correction value (α) to produce an adjusted output signal (Φₑ′) of the digital phase detector;
a loop filter configured to receive the adjusted output signal (Φₑ′) of the digital phase detector and generate a digital output signal (OTW);
a second adjusting unit configured to adjust the digital output signal (OTW) of the loop filter by a second correction value (β) to produce the digital input signal (OTW_{DAC}) to the R-DAC; and
a digital processing unit;
the method comprising:
generating by the digital processing unit, a first and second setting values (DAC_{S1}, DAC_{S2}) to set the first and second reference voltages (Vref1, Vref2) so that the output of the R-DAC is in a first output range during a starting stage of the PLL system;
determining if the PLL system is in a lock stage by monitoring the value of the control signal (Vctrl) to the VCO or the digital input signal (OTW_{DAC}) value to the R-DAC;
when the PLL system is in the lock stage,
determining by the digital processing unit, a second output range of the R-DAC;
determining by the digital processing unit, a number of steps (K1, K2) for each of the first and second reference voltages (Vref1, Vref2) to be changed stepwise;
determining by the digital processing unit, a number of clock cycles for each of the first and second reference voltages (Vref1, Vref2) to be kept at each step;
calculating a step size value for each of the first and second reference voltages (Vref1, Vref2) based on the number of steps, the second output range of the R-DAC and the value of the control signal (Vctrl) to the VCO; and for each step k, k=1, 2 . . . K1/K2,
generating a first and a second setting values (DAC_{S1}, DAC_{S2}) based on the step size values to set the first and second reference voltages (Vref1, Vref2);
calculating a first correction value (α) based on a difference between the first and second reference voltages (Vref1, Vref2) at the k-th step;
adjusting the output signal (Φₑ) of the digital phase detector by the first correction value (α);
calculating a second correction value (β) based on the second correction value at the (k−1)-th step, the digital input signal range of the R-DAC, the first and second reference voltages (Vref1, Vref2) at the (k−1)-th and k-th steps, and the value of the digital input signal (OTW_{DAC}) to the R-DAC at (k−1)-th step;
adjusting the digital output signal (OTW) of the loop filter by the second correction value (β) to produce the digital input signal (OTW_{DAC}) to the R-DAC;
generating by the R-DAC, a control signal (Vctrl) to the VCO based on the digital input signal (OTW_{DAC}) to tune the frequency of the output signal (Out) generated by the VCO.

16. The PLL system according to claim 2, wherein the digital processing unit is configured to generate the first and second setting values (DAC_{S1}, DAC_{S2}) to set the first and second reference voltages (Vref1, Vref2) such that the R-DAC operates in a first output range during a starting stage of the PLL system.

17. The PLL system according to claim 3, wherein the digital processing unit is configured to generate the first and second setting values (DAC_{S1}, DAC_{S2}) to set the first and second reference voltages (Vref1, Vref2) such that the R-DAC operates in a first output range during a starting stage of the PLL system.

18. The PLL system according to claim 2, wherein the first adjusting unit is configured to adjust the output signal (Φₑ) of the digital phase detector by multiplying the output signal (Φₑ) of the digital phase detector with the first correction value (α) or by dividing the output signal (Φₑ) of the digital phase detector by the reciprocal of the first correction value (1/α).

19. The PLL system according to claim 3, wherein the first adjusting unit is configured to adjust the output signal (Φₑ) of the digital phase detector by multiplying the output signal (Φₑ) of the digital phase detector with the first correction value (α) or by dividing the output signal (Φₑ) of the digital phase detector by the reciprocal of the first correction value (1/α).

20. The PLL system according to claim 2, wherein the second adjusting unit is configured to adjust the digital output signal (OTW) of the loop filter by adding the second correction value (β) to the digital output signal (OTW) or by subtracting the negation of the second correction value (−β) from the digital output signal (OTW).
